(19) United States
(12) Patent Application Publication
(10) Pub. No.: US 2025/0279130 A1
(43) Pub. Date: Sep. 4, 2025

(54) Efficient Dram Refresh Management Using Graded Refresh Alert Levels

(71) Applicant: Google LLC, Mountain View, CA (US)

(72) Inventors: Nagaraj Ashok Putti, Cupertino, CA (US); Venkateswaran Ananthanarayanan, Karnataka (IN)

(21) Appl. No.: 18/850,432

(22) PCT Filed: Mar. 24, 2022
(86) PCT No.: PCT/US2022/021646

§ 371 Date: Sep. 24, 2024

(51) Int. Cl. G11C 11/406

(52) U.S. Cl. CPC G11C 11/40618; G11C 11/40603; G11C 11/40615

(57) ABSTRACT

This specification describes memory controllers for dynamic random-access memory (DRAM). In one aspect, a memory system includes DRAM that includes DRAM banks. The memory system includes a memory controller for managing the DRAM. The memory controller includes a request scheduler configured to receive memory transactions and send memory request commands to the DRAM banks. The memory controller includes a refresh scheduler configured to monitor a status of a dynamically changing refresh requirement for the DRAM, determine an alert level for the DRAM based at least in part on the status of the refresh requirement, and manage, based on the determined alert level, the DRAM banks to which refresh commands are sent and the memory transactions for which memory request commands are sent by the request scheduler.

### TECHNICAL FIELD

This specification relates to dynamic random-access memory (DRAM) memory controllers.

### BACKGROUND

A DRAM cell is a memory cell that typically includes an access transistor and a capacitor for storing a bit of data. The capacitor can either be charged or discharged to represent the two values of a bit, zero or one. The capacitor tends to leak its stored charge over time. Thus, without intervention, the data stored in DRAM would be lost. To prevent this data loss, the data stored in DRAM is refreshed periodically, e.g., using refresh commands issued by a DRAM memory controller. Each DRAM cell must be refreshed periodically based on applicable DRAM standards, e.g., the JEDEC memory standards. Refreshing a DRAM cell typically includes reading and rewriting the data to the DRAM cell, which restores the capacitor to its previous charge.

The refresh process negatively affects the performance and power usage/dissipation of the DRAM cells. For example, the DRAM cells of a DRAM bank are stalled during the refresh process, preventing data from being read from or written to the DRAM bank. The refresh process also increases the amount of power used and dissipated by the memory systems due to the reading and rewriting of data to the DRAM cells.

### SUMMARY

This specification relates to dynamic random-access memory (DRAM) memory controllers. In some DRAM systems, an access to DRAM typically includes a sequence of an activate (ACT) command to open a row of a DRAM bank, a column read or write (COL) command to perform the read/write operation on a subset of the DRAM cells within the row, and a precharge (PRE) command to close the row. Once a row is open, the row can be accessed multiple times through a series of COL commands. But once closed using the PRE command, the row must be opened again using an ACT command to enable access to the row of data.

As the bits of DRAM memory need to be periodically refreshed to retain their values, a DRAM memory controller can periodically send refresh commands to the rows of the DRAM banks. In some DRAM systems, a refresh command refreshes one row of bits of a DRAM bank while the row is closed. If a row of a DRAM bank does not receive the refresh command within the prescribed interval, the bits of that row are at risk of being corrupted. Therefore, refresh is needed to maintain the integrity of the DRAM. However, each time a REF command is sent, it creates a black-out period for regular memory read/write commands, not just to the row to which the refresh command is targeted (“target row”), but to all rows of all banks of the DRAM in different proportions. Typically, the rows of the same DRAM bank as the target row experience a larger black-out period compared to rows of other banks.

As memory refreshes negatively impact the overall throughput of the DRAM systems, several architectural improvements can be implemented to mitigate the throughput implications, thereby increasing the overall throughput of the DRAM system. One improvement is the use of per-bank refresh (REFpb) commands that refresh the rows of one bank at a time rather than an all-bank refresh (REFab) command that refreshes the rows of all banks at a time. A REFab command causes all banks within the DRAM system to be unavailable until all of the DRAM banks are refreshed. Using REFpb commands enable access to other DRAM banks while a target DRAM bank is being refreshed. While REFpb involves targeted refreshing of a bank or a bank group (e.g., bank pair) and allows traffic to continue onto other banks, REFab requires traffic to be stalled to all banks and all banks to be in an idle state before the start of the REFab command. One REFab command can be equivalent to issuing eight REFpb commands and has the same effect in DRAM systems having eight bank groups. A bank group can include one or more DRAM banks.

A memory controller can include a refresh scheduler that schedules refreshes to DRAM banks, e.g., on a per-bank basis and/or for all banks managed by the memory controller. A refresh scheduler typically issues per-bank refresh (REFpb) commands to DRAM banks that are closed unless the refresh interval for the DRAM system is close to lapsing. If so, the refresh scheduler can issue a refresh all banks command (REFab) command to refresh all of the DRAM banks.

When memory traffic is ongoing, it is desirable to issue more REFpb commands than REFab commands as it aids system performance by avoiding blackout periods for the DRAM system. The JEDEC standards provide flexibility in choosing the order in which bank pairs are selected while issuing the REFpb command for each cycle and the order can be different for each cycle. Each cycle is defined as one iteration across all the banks within a refresh (tREFi) window. A memory controller can typically only issue REFpb to a bank pair once during the cycle and the memory controller has to finish iterating through all bank pairs before starting another cycle. This enables the memory controller to implement schemes that could potentially result in better system performance by choosing an improved or optimal order of DRAM banks to refresh in each cycle.

Another memory refresh improvement is the ability to prepone and/or postpone REF commands within specified limits such that the overall refresh requirements are still met on average. The ability to prepone and postpone REF commands provides the flexibility to the DRAM memory controller to schedule the REF commands by adapting to the temporal traffic patterns for accessing the DRAM to further improve the performance of the DRAM system.

According to the Joint Electron Device Engineering Council (JEDEC) standards, the expectation is for a REF command to be sent within a refresh interval (tREFi). A REF command refers to a refresh command sent to all DRAM banks or for one REF command, e.g., a REFpb command, to be sent to each bank within a refresh interval (tREFi). In other words, a REF command refers to some form of a refresh command being sent to all banks of the DRAM system during a refresh time interval. The refresh interval can depend on the DRAM type and operating conditions.

The JEDEC standards allow postponement of the REF command of multiple contiguous refresh intervals up to a specified limit (ref_max_postpone). Similarly, the JEDEC standards allow preponement (REF command issued early) of multiple refresh intervals up to a specified limit (ref_max_prepone). That is, the REF command for a DRAM system can be delayed for multiple intervals up to a specified quantity (ref_max_postpone) of refresh intervals and/or issued early for up to a specified quantity (ref_max_prepone) of refresh intervals according to the JEDEC standards.

When the DRAM system has preponed to the specified limit, it just means that the memory controller can temporarily take a break from trying to schedule REF commands. However, when the DRAM system has postponed to the specified limit, it means that the memory controller has to block all other memory commands to allow the REF command, e.g., a REFab command, to be processed and ensure that the next refresh interval is not missed. If it is missed, then the data integrity of the data stored in DRAM has been compromised.

In situations in which the DRAM system is approaching the hard refresh deadline, the memory controller can issue, e.g., send, a REFab command to refresh all DRAM banks. To send the REFab command at the right time, no other command can be allowed to be issued up to a margin time period (tREFmargin) prior to the hard deadline. However, this black-out period can impact all pending read and write commands irrespective of their priority requirements. Furthermore, if a high traffic condition persists, then subsequent refresh intervals may experience a blackout period as the DRAM system would be in hard deadline mode until the memory controller is able to send more than one REF command and catches up.

The treatment of high priority requests, particularly during such blackout periods, is a key indicator of a DRAM system's overall quality of service (QOS). Any improvement to the memory controller's overall QOS positively impacts the entire system that includes the DRAM. One such way is to re-order the memory traffic by being aware of the impending refresh requirements. Similar to the memory system throughput, overall system QOS is a key performance metric of a DRAM system. Assuming each incoming transaction (e.g., memory read or write request) to the memory controller includes a QOS priority value, which can indicate the transaction's relative priority, the weighted average system latency can be defined using Equation 1:

$$weighted\_average \_latency = \frac{{\sum }_{i = 0}^{N transaction} k [ i ] * QOS [ i ] * latency [ i ]}{{\sum }_{i = 0}^{N transaction} k [ i ] * QOS [ i ]}$$

In Equation 1, the parameter “k” is a scaling factor based on the corresponding QOS priority value (QOS[i]) for each transaction “T” and latency[i] is the latency of transaction i. As opposed to the usual average latency, the weighted average latency (weighted average latency) of Equation 1 provides a better indication of how the DRAM system is handling high priority transactions as compared to lower priority transactions. When the weighted average latency is lower than the non-weighted average latency and the non-weighted average latency is higher than usual, it means that the DRAM system is experiencing delays (e.g., due to refresh blackout periods), but the higher priority requests are not as impacts as lower priority requests. The weighted average latency metric of Equation 1 is an indicator of how well the system is able to adapt itself between changing traffic conditions and system black-out periods.

The memory controllers and techniques described in this document consider impending refresh requirements of the DRAM and manage incoming memory requests according to the impending refresh requirements. The controllers can take into account the impending refresh requirements and manage, e.g., schedule, transactions based on the refresh requirements and the priority values for the transactions in ways that improve the weighted average and overall system QOS. In some implementations, the memory controllers are configured to assign the DRAM systems to various alert levels based on the impending refresh requirements and manage transactions based on the current alert level and, during some alert levels, the priority values of the transactions. In this way, the memory controller can place higher priority on higher priority transactions as the DRAM gets closer to the hard refresh deadline, but allow lower priority transactions to proceed to DRAM when further from the hard refresh deadline.

In general, one innovative aspect of the subject matter described in this specification can be embodied in a memory system that includes DRAM including multiple DRAM banks arranged in a set of DRAM bank groups each comprising one or more DRAM banks and a memory controller for managing the DRAM. The memory includes a request scheduler configured to receive memory transactions and send memory request commands to the DRAM banks. The refresh scheduler is configured to monitor a status of a dynamically changing refresh requirement for the DRAM, determine an alert level for the DRAM based at least in part on the status of the refresh requirement, and manage, based on the determined alert level, the DRAM banks to which refresh commands are sent and the memory transactions for which memory request commands are sent by the request scheduler.

These and other implementations can each optionally include one or more of the following features. In some aspects, the status of the refresh requirement includes a duration of time until an occurrence of a deadline by which all DRAM banks of the DRAM must be refreshed. The refresh scheduler can be configured to manage the DRAM banks to which refresh commands are sent and the memory transactions for which memory request commands are sent by the request scheduler based further on a priority value for each memory transaction.

In some aspects, the refresh scheduler is configured to manage the DRAM banks to which refresh commands are sent based on a combination of the determined alert level and a status of each DRAM bank. The status of each DRAM bank can include an indication of whether the DRAM bank is open or closed. The refresh scheduler can be configured to manage the DRAM banks to which refresh commands are sent based further on a priority value for memory transactions for each DRAM bank.

In some aspects, the refresh scheduler is configured to manage the DRAM banks to which refresh commands are sent by proactively sending precharge commands to DRAM banks based on a combination of the determined alert level and a status of the DRAM banks.

In some aspects, the refresh scheduler is configured to manage the memory transactions for which memory request commands are sent by the request scheduler based on a combination of the determined alert level and a type of memory request command to be sent to each DRAM bank for which a memory transaction has been received. The refresh scheduler can be configured to (i) block ACT commands for non-priority memory transactions for a first alert level and (ii) block all ACT commands and COL commands for memory transactions for a second alert level that is higher than the first alert level.

In general, another innovative aspect of the subject matter described in this specification can be embodied in a method performed by a memory controller configured to manage DRAM including a multiple DRAM banks arranged in a set of DRAM bank groups each including one or more DRAM banks. The method includes receiving, by a request scheduler of the memory controller, memory transactions for the DRAM; sending, by the request scheduler, memory request commands to the DRAM banks based on the received memory transactions; monitoring, by the refresh scheduler, a status of a dynamically changing refresh requirement for the DRAM; determining, by the refresh scheduler, an alert level for the DRAM based at least in part on the status of the refresh requirement; and managing, by the refresh scheduler and based on the determined alert level, the DRAM banks to which refresh commands are sent and the memory transactions for which memory request commands are sent by the request scheduler.

These and other implementations can each optionally include one or more of the following features. In some aspects, the status of the refresh requirement comprises a duration of time until an occurrence of a deadline by which all DRAM banks of the DRAM must be refreshed. The refresh scheduler can manage the DRAM banks to which refresh commands are sent and the memory transactions for which memory request commands are sent by the request scheduler based further on a priority value for each memory transaction.

In some aspects, the refresh scheduler manages the DRAM banks to which refresh commands are sent based on a combination of the determined alert level and a status of each DRAM bank. The status of each DRAM bank can include an indication of whether the DRAM bank is open or closed. The refresh scheduler can manage the DRAM banks to which refresh commands are sent based further on a priority value for memory transactions for each DRAM bank.

In some aspects, the refresh scheduler manages the DRAM banks to which refresh commands are sent by proactively sending precharge commands to DRAM banks based on a combination of the determined alert level and a status of the DRAM banks. The refresh scheduler can manage the memory transactions for which memory request commands are sent by the request scheduler based on a combination of the determined alert level and a type of memory request command to be sent to each DRAM bank for which a memory transaction has been received.

In some aspects, the refresh scheduler is configured to (i) block ACT commands for non-priority memory transactions for a first alert level and (ii) block all ACT commands and COL commands for memory transactions for a second alert level that is higher than the first alert level.

In general, another innovative aspect of the subject matter described in this specification can be embodied in a memory controller that includes a request scheduler configured to receive memory transactions and send memory request commands to dynamic random-access memory (DRAM) comprising DRAM banks arranged in a set of DRAM bank groups each comprising one or more DRAM banks. The memory controller includes a refresh scheduler configured to monitor a status of a dynamically changing refresh requirement for the DRAM, determine an alert level for the DRAM based at least in part on the status of the refresh requirement, and manage, based on the determined alert level, the DRAM banks to which refresh commands are sent and the memory transactions for which memory request commands are sent by the request scheduler. The status of the refresh requirement can include a duration of time until an occurrence of a deadline by which all DRAM banks of the DRAM must be refreshed.

The subject matter described in this specification can be implemented in particular embodiments so as to realize one or more of the following advantages. By managing memory transactions, e.g., read requests and write requests, based on impending refresh requirements of DRAM, a memory controller can improve the performance, e.g., latency and throughput, of the DRAM and the overall QOS of the system that includes and/or uses the DRAM. For example, memory controllers can reduce the occurrences of blackout periods related to all-bank refreshes and ensure that higher priority transactions are completed over lower priority requests in situations in which the DRAM is trending towards a hard refresh deadline. The memory controllers can also more efficiently schedule refreshes to DRAM bank groups based on impending refresh requirements to delay and/or reduce the number of occurrences of all-bank refreshes. For example, the memory controllers can proactively issue REFpb commands to lower priority open DRAM bank groups when the alert level for the DRAM system is higher while enabling higher priority transactions to proceed to DRAM to reduce the number of DRAM bank groups that need to be refreshed as the hard refresh deadline approaches. If the alert level increases from this point, the memory controller can block all traffic and issue REFpb commands to DRAM bank groups that still need a refresh in an attempt to avoid issuing a REFab command. By progressively blocking more transactions (e.g., starting from lower priority transactions and moving to higher priority transactions), as the DRAM system gets closer to a hard refresh deadline, the memory controller can delay and reduce the number of all-bank refresh blackouts, resulting in higher throughput, reduced latency, and higher overall QOS. Blocking memory transactions can include delaying the transactions for a period of time to allow for refreshes to occur and then processing the transactions at a later time.

The details of one or more embodiments of the subject matter of this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1A shows an example memory system in which a memory controller controls access to DRAM and refreshes DRAM cells of the DRAM.

FIG. 1B shows the example DRAM of FIG. 1A.

FIG. 2 shows a flow diagram of an example process for refreshing DRAM cells.

FIG. 3 shows a diagram that includes a timeline of refresh intervals, memory traffic levels, and alert levels.

Like reference numbers and designations in the various drawings indicate like elements.

### DETAILED DESCRIPTION

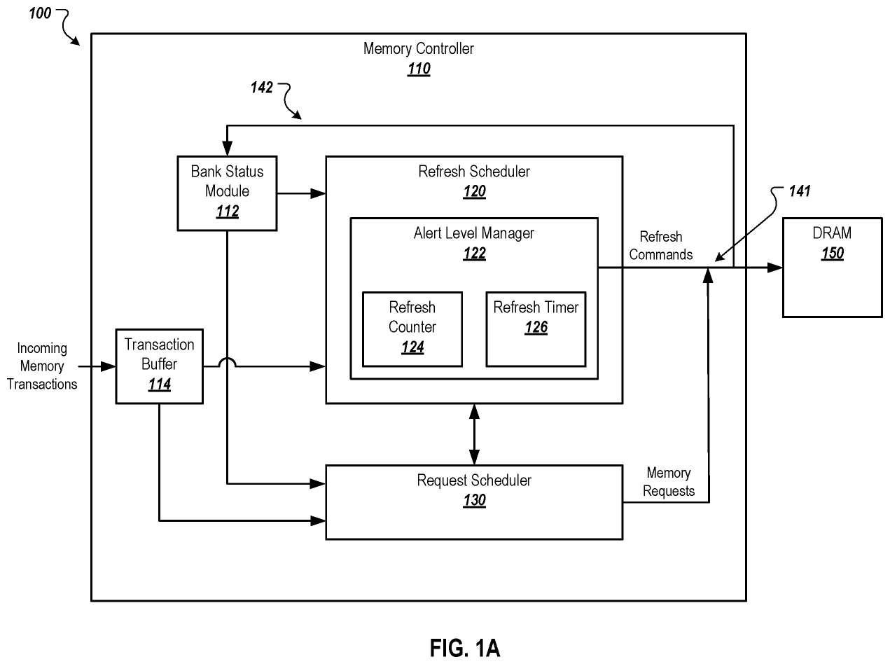

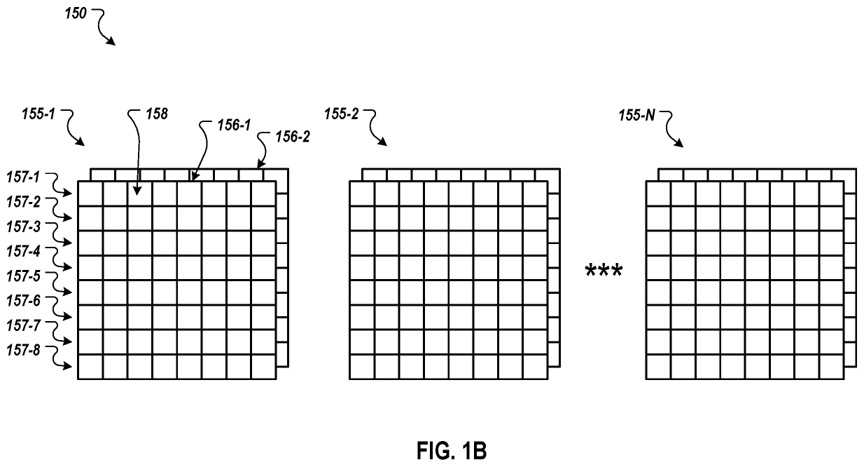

FIG. 1A shows an example memory system 100 in which a memory controller 110 controls access to DRAM 150 and refreshes DRAM cells of the DRAM 150. The DRAM can include multiple DRAM banks that each include one or more rows of DRAM cells. Each row can include multiple DRAM cells. A DRAM cell typically includes an access transistor and a capacitor for storing a value of a bit of data, e.g., a value of one if charged or a value of zero if discharged. The DRAM 150 can be implemented as low power double data rate (LPDDR) DRAM or other appropriate types of DRAM. Although the example memory system 100 includes DRAM, the memory system 100 and its components and functionality can be implemented for other types of memories that require refreshing.

Each DRAM bank can be arranged as a two-dimensional array of DRAM cells having multiple rows and columns. A DRAM row can also be referred to as a DRAM page. The DRAM banks can be arranged in groups that are refreshed together as a group. For example, the DRAM banks can be arranged as bank pairs that each include two DRAM banks. A DRAM bank group can include one or more DRAM banks.

Referring to FIG. 1B, the example DRAM 150 includes a number “N” DRAM bank pairs 155-1 to 155-N. Each DRAM bank pair 155 includes two DRAM banks 156-1 and 156-2 that each include DRAM cells 156 arranged in eight rows 157-1 to 157-8 and eight columns. In other examples, the DRAM 150 can include DRAM groups that each have a single DRAM bank or more than two DRAM banks, and/or each DRAM bank can include a different number of rows and/or a different number of columns. For example, another DRAM system can have DRAM bank pairs with 16×16 DRAM banks, 32×32 DRAM banks, or other appropriately sized DRAM banks.

Referring back to FIG. 1A, the memory controller 110 includes a refresh scheduler 120, a bank status module 112, a transaction buffer 114, and a request scheduler 130. Of course, the memory controller 110 and the memory system 100 can include additional components that are not shown in FIG. 1, such as decoders, address buffers, registers, etc.

The transaction buffer 114 receives incoming memory transactions for reading data from and writing data to the DRAM 150 and temporarily stores the transactions. For example, the memory transactions can be received from a central processing unit (CPU), a graphics processing unit (GPU), or another type of processor or component, e.g., over a memory bus or other interface that connects the processor or component to the memory system 100.

An incoming memory transaction can have a corresponding priority value, e.g., that is provided with the transaction. For example, a processor can send, to the memory controller 110, memory transactions that include a command to read data from or write data to DRAM 150 and a priority value corresponding to the request. The priority value can be represented by a number within a numerical range, e.g., zero to ten or another appropriate range, or as a particular level, e.g., low, moderate, or high. In another example, the processor can label some memory transactions as priority transactions and either label non-priority requests as low priority transactions or not include a label for non-priority transactions. The priority value can be a QOS priority value.

The request scheduler 130 monitors the transaction buffer 114 for incoming memory transactions that are buffered at the transaction buffer 114. The request scheduler 130 also generates and sends requests to access, e.g., read data from and write data to, DRAM cells of the DRAM 150 over a command path 141 in response to receiving the memory transactions. In some DRAM systems, an access to DRAM 150 typically includes a sequence of an activate (ACT) command to open a row of a DRAM bank, a column (COL) read or write command to perform the read/write operation on a subset of the DRAM cells within the row, and a precharge (PRE) command to close the row. Once a row is open, the row can be accessed multiple times through a series of COL commands. Once closed using the PRE command, the row can be opened again using the ACT command to access the row again. The request scheduler 130 can issue these memory request commands based on memory transactions received by the transaction buffer 114.

The bank status module 112 can maintain the status of each DRAM bank and/or row of each bank. As described above, the DRAM banks can be arranged as bank pairs or other sized bank groups. The status of a bank pair can indicate whether one of the DRAM banks of the bank pair is open. For example, the status can be a bit having a first value, e.g., one, when one DRAM bank is open, and second value, e.g., zero, when either both DRAM banks are open or both DRAM banks are closed. In another example, the status can indicate the number of banks open, e.g., zero, one, or two.

The status of a DRAM bank can also indicate a priority value of a memory transaction for the DRAM bank. For example, the status of a DRAM bank can indicate the priority value of a pending memory transaction for the DRAM bank if one is pending or the priority value of the most recently received memory transaction for the DRAM bank.

The bank status module 112 can update the status of DRAM banks based on commands sent to DRAM 150. For example, the bank status module 112 can receive the commands being sent to DRAM 150 on a feedback path 142 connected to a command path 141 over which the commands are sent to DRAM 150. The bank status module 112 can update the status of a DRAM bank, bank pair, or row based on a received command. For example, if the request scheduler 130 sends an ACT command for a row to DRAM 150, the bank status module 112 can update the status of the row and the DRAM bank in which the row is included to a status of “open” in response to receiving the ACT command for the row on the feedback path 142. The bank status module 112 can determine the number of DRAM banks open in the bank pair that includes the now open DRAM bank and row and update the status of the bank pair based on the determined number.

The refresh scheduler 120 schedules refreshes and issues refresh commands, e.g., REFpb and REFab, to the DRAM banks of the DRAM 150 over the command path 141. As described above, a REFpb command is a command to refresh a particular DRAM bank or pair of banks and a REFab is a command to refresh all banks of DRAM 150 in the memory system 100. In general, the refresh scheduler 130 issues REFpb commands to DRAM banks that are closed during the refresh interval for the DRAM 150 to prevent or delay having to issue a REFab command to refresh all banks. When issuing REFpb commands to pairs of banks, the refresh scheduler 130 can issue REFpb commands to pairs of banks for which both banks are closed.

The refresh scheduler 120 manages the commands sent to the DRAM 150 based on refresh requirements of the DRAM 150. The refresh scheduler 120 can schedule refreshes, e.g., REFpb commands and REFab commands, based on the refresh requirements. The refresh scheduler 120 can also interact with the request scheduler 130 to manage memory requests sent to the DRAM 150 based on the refresh requirements. For example, the refresh scheduler 120 can manage the commands sent to the DRAM 150 based on a hard deadline by which all cells of the DRAM 150 must be refreshed to avoid compromising the integrity of data stored in the DRAM 150, e.g., based on a duration of time until the hard deadline would occur. As described above, the hard deadline can change dynamically based on refresh commands sent to the DRAM 150. For example, the refresh scheduler 120 can prepone the refresh commands by refreshing all of the cells early up to a specified preponement limit (ref_max_prepone), which delays the hard deadline.

The refresh scheduler 120 includes an alert level manager 122 that determines an alert level for refreshing the DRAM 150 based on the status of the refresh requirement. For example, the refresh scheduler 120 can determine the alert level based on a duration of time until the hard deadline occurs. In general, the alert level indicates the urgency in refreshing the DRAM banks to avoid having to issue a REFab command that would black-out the DRAM 150 while all banks of the DRAM 150 are refreshed. The refresh scheduler 120 can manage the commands sent to the DRAM 150 based on the current alert level determined by the alert level manager 122, as described in more detail below.

The alert level manager 122 includes a refresh counter 124 and a refresh timer 126. The refresh counter 124 tracks the quantity of refresh periods for the DRAM 150. The refresh counter 124 can increment by one unit each time the duration of time of the refresh interval (tREFi) has elapsed without completely satisfying the refresh requirements of the DRAM 150, e.g., without refreshing every cell of the DRAM 150. The refresh counter 124 can also decrement by one unit each time the refresh requirements for one tREFi duration is completely satisfied, e.g., when every cell of the DRAM 150 is refreshed by sending out appropriate REF commands to all rows of all banks of the DRAM 150 during a refresh interval. When the refresh counter 124 increments by one unit, it means that the refresh for the DRAM 150 has been postponed by one unit. Similarly, when the refresh counter 124 decrements by one unit, it means that the refresh for the DRAM 150 has been preponed by one unit. The count of the refresh counter 124 must remain between the specified preponement limit (ref_max_prepone) and the specified postponement limit (ref_max_postpone). The conditions on the refresh counter 124 can be represented as: −ref_max_prepone≤ref_counter≤ref_max_postpone, where ref_counter is the count of the refresh counter 124.

The refresh timer 126 tracks the time within a refresh interval. The refresh timer 126 can track the time within the refresh interval to the granularity of the system clock, e.g., of the clock of a computer or other system that includes the DRAM 150. There can be certain command-to-command timing requirements specified in the standards or other requirements followed by the memory controller 110, e.g., the JEDEC standards. For example, there can be a maximum margin time interval required to actually issue a refresh command after any other command is sent. This maximum margin time interval can be referred to as tREFmargin. To send a REFab command right before the hard refresh deadline, no other command can be allowed to be issued to the DRAM 150 up to tREFmargin prior to the hard deadline.

The postponable refresh window can start at a time when there are no refreshes postponed or preponed, e.g., when the refresh counter 124 has a count equal to zero. The postponable refresh window ends at a future point in time, which can be referred to as tREFmust, when the memory controller 110 has postponed the maximum allowed REF commands, e.g., to the specified postponement limit and it at the last tREFi window. For example, if the specified postponement limit is eight postponements, this would be when the count of the refresh counter 124 is seven and the memory controller 110 is in the eighth tREFi window. In other words, the future point in time tREFmust can be considered a time at which the hard refresh deadline occurs and a REFab command must be sent to avoid compromising the integrity of the data stored in the DRAM 150.

In general, as the memory controller 110 issues or misses REF commands due to memory traffic conditions, tREFmust points to a time in the future at which the hard refresh deadline will be encountered assuming no refresh commands (either REFpb or REFab) are issued until then. As the memory controller 110 issues REF commands, if and when it can, the tREFmust point at which the hard refresh deadline may occur dynamically changes by moving forward in time. The alert level manager 122 can use the refresh counter's current count to assess the criticality of the memory system 100 with respect to an impending refresh deadline. In some implementations, the future point in time of the hard deadline tREFmust can be calculated using Equation 2:

$$tREFmust = tcurrent + ( ref\_max \_postpone - ref\_counter ) \times tREFi + tREFi$$

In Equation 2, tcurrent refers to the current time, ref_max_postpone refers to the specified postponement limit, ref_counter refers to the current count of the refresh counter 124, and tREFi is the refresh interval.

The alert level manager 122 can use various time values to determine an alert level for the DRAM 150 and/or the memory system 100 as a whole. For example, the alert level manager 122 can determine an alert level based on the future point in time of the hard refresh deadline (tREFmust), the current time (tcurrent), and/or the margin time period (tREFmargin).

The alert level manager 122 can use any quantity M of alert levels, which can vary based on the implementation of the memory system 110. The alert levels can be graded such that higher alert levels represent elevated urgency for refreshing the DRAM banks of the DRAM 150. For example, there can be M alert levels from alert level zero (ALERT_LVL[0]) to alert level M-1 (ALERT_LVL[M-1]) such that alert level M-1 has the highest urgency and alert level zero has the lowest urgency level. Such a graded approach provides an early indication to the refresh scheduler 120 to interact with the request scheduler 130 to act in tandem with the refresh requirements, thereby delaying and/or reducing the chances of reaching the hard refresh deadline. It also enables the refresh scheduler 120 to adjust the actions taken to prevent the occurrence of the hard refresh deadline with increases in the alert level, while not taking such actions when unnecessary. For example, the refresh scheduler 120 can communicate the alert level to the request scheduler 130 and can instruct the request scheduler 130 to deprioritize regular read and write memory requests at an increasing rate or using more aggressive techniques with an increase in alert level to enable more refresh requests to be sent to the DRAM 150.

In some implementations, the alert level manager 122 maps different mutually exclusive time periods to the alert levels. The time periods can be based at least on the current time (tcurrent) and future point in time of the hard refresh deadline (tREFmust), e.g., based on differences between tcurrent and tREFmust. The time periods can also be based on the refresh interval (tREFi) and margin time period (tREFmargin). An example of a four-level graded alert level protocol is shown below in Table 1. Other quantities and definitions of alert levels can also be used.

TABLE 1

| Alert Level | Definition |
|---|---|
| 0 | tcurrent < (tREFmust − (2 × tREFi)) |
| 1 | (tREFmust − (2 × tREFi)) ≤ tcurrent < |
| | (tREFmust − tREFi) |
| 2 | (tREFmust − tREF) ≤ tcurrent < (tREFmust − ref_margin) |
| 3 | tcurrent ≥ (tREFmust − ref_margin) |

In this example, alert level 0 is a level at which there is low risk of an impending hard refresh deadline. When the current time is less than the difference between the current value of the time of the hard refresh deadline and twice the refresh interval, the alert level manager 122 can determine that the current alert level is alert level 0. In other words, when the DRAM 150 is greater than two refresh intervals from the hard refresh deadline, there is low risk and the current alert level is alert level 0.

Alert level 1 is a level at which there is a moderate risk of an impending hard refresh deadline. When the current time is between (i) the difference between the current value of the time of the hard refresh deadline and twice the refresh interval and (ii) the difference between the current value of the time of the hard refresh deadline and the refresh interval, the alert level manager 122 can determine that the current alert level is alert level 1. In other words, when the hard refresh deadline is between one and two refresh intervals from the current time, there is a moderate risk and the current alert level is alert level 1.

Alert level 2 is a level at which there is high risk of an impending hard refresh deadline. When the current time is between (i) the difference between the current value of the time of the hard refresh deadline and the refresh interval and (ii) a difference between the current value of the time of the hard refresh deadline and the margin time period, the alert level manager 122 can determine that the current alert level is alert level 2. In other words, when the hard refresh deadline is between one refresh interval and the margin time period from the current time, there is a high risk and the current alert level is alert level 2.

Alert level 3 is a level at which there is a critical risk of an impending hard refresh deadline. When the current time is greater than or equal to a difference between the current value of the time of the hard refresh deadline and the margin time period, the alert level manager 122 can determine that the current alert level is alert level 3. In other words, when the hard refresh deadline is at or within the margin time period of occurring, there is a critical risk and the alert level is alert level 3.

The refresh scheduler 120 can be configured to adjust how it manages refreshes sent to the DRAM 150 based on the alert level. The refresh scheduler 120 can also interact with the request scheduler 130 to adjust how the request scheduler 130 manages memory requests sent to the DRAM 150 based on the alert level.

The refresh scheduler 120 can manage the refreshes based on alert level by enabling and/or blocking types of refreshes for the various alert levels. For example, if the alert level is a low alert level, e.g., alert level 0 of the example of Table 1, the refresh scheduler 120 may issue refresh commands only during idle periods. That is, the refresh scheduler 120 can proactively refresh DRAM bank groups when the DRAM groups are idle while refraining from refreshing DRAM bank groups that are being accessed by the request scheduler 130 when the alert level is low. The refresh scheduler 120 can also instruct the request scheduler 130 to operate normally by sending memory request commands to the DRAM 150 according to its normal scheduling protocol. Functionally speaking, the refresh scheduler 120 and the request scheduler 130 operate normally at this alert level.

When the alert level is at an increased level, e.g., for a moderate risk level such as alert level 1 in the example of Table 1, the refresh scheduler 120 can instruct the request scheduler 130 to block, e.g., refrain from sending or delay sending, some memory request commands to the DRAM. For example, the refresh scheduler 120 can instruct the request scheduler 130 to block some types of memory request commands for some DRAM banks having particular statuses. In a particular example, the refresh scheduler 120 can instruct the request scheduler 130 to block activate (ACT) commands from being sent to pending non-priority DRAM banks. A non-priority DRAM bank can be a DRAM bank to which there are no recently received priority transactions (e.g., transactions having at least a threshold priority value received within a threshold time period from a current time) and/or no pending priority transactions that have not yet been completed. The refresh scheduler 120 can continue sending ACT commands to priority DRAM banks and COL commands to all DRAM banks. A priority DRAM bank is a DRAM bank to which there is at least one recently received priority transaction.

When the alert level is at this increased level, the refresh scheduler 120 can also be configured to proactively refresh some DRAM banks. For example, the refresh scheduler 120 can proactively refresh DRAM banks having a particular status. In a particular example, the refresh scheduler 120 can proactively send precharge (PRE) commands to DRAM banks to pending non-priority DRAM banks. The PRE commands close the rows of the DRAM banks so that the refresh scheduler 120 can refresh the rows of the DRAM banks. The functionality of the refresh scheduler 120 and the request scheduler 130 at this alert level prevents new openings of non-priority rows, but allows pending COL/PRE activities on already opened rows.

When the alert level is at a high level, e.g., alert level 2 of the example of Table 1, the refresh scheduler 120 can instruct the request scheduler 130 to block additional memory requests relative to lower alert level(s). For example, the refresh scheduler 120 can instruct the request scheduler 130 to block additional types of memory request commands and/or for additional statuses of DRAM banks relative to lower alert level(s). In a particular example, the refresh scheduler 120 can instruct the request scheduler 130 to block ACT commands from being sent to all DRAM banks and to block column read or write (COL) commands to pending non-priority DRAM banks.

When the alert level is at this high level, the refresh scheduler 120 can also be configured to proactively refresh some DRAM banks. In a particular example, the refresh scheduler 120 can proactively send precharge (PRE) commands to DRAM banks to pending non-priority DRAM banks. The functionality of the refresh scheduler 120 and the request scheduler 130 at this alert level prevents new openings of any rows, and only allows pending priority COL activities to finish on already opened rows. As there is a significant time penalty associated with opening and closing rows, preventing the row access by controlling not just COL commands but also the ACT commands helps in smoothing the refresh risk.

When the alert level is critical, e.g., alert level 3 of the example of Table 1, the refresh scheduler 120 can instruct the request scheduler to block additional memory requests relative to lower alert level(s). For example, the refresh scheduler 120 can instruct the request scheduler 130 to block all commands sent to the DRAM banks except PRE and REF commands. This prevents commands other than those used to refresh from reaching the DRAM 150. In other words, the refresh commands take precedence over all other commands so that the hard refresh deadline is not missed, thereby preventing the integrity of the data stored in the DRAM 150 from being compromised.

In some implementations, the refresh scheduler 120 can send the alert level to the request scheduler 130. The request scheduler 130 can be configured to block certain commands from being sent to DRAM 150 based on the current alert level. For example, the request scheduler 130 can be configured to block commands as described above for alert levels 0-3 depending on the current alert level.

By reducing the amount of regular memory requests sent to the DRAM 150 as the alert level increases, more refresh commands, e.g., REFpb commands, can be sent to DRAM banks as more DRAM banks become idle. This increases the likelihood that all of the cells of the DRAM 150 can be refreshed during a refresh interval thereby reducing the likelihood of reaching the hard refresh deadline.

The graded alert levels can impose selective back-pressure such that the likelihood of issuing a REFab command becomes higher, e.g., gradually through the alert levels. Anytime a REFab command is issued, it leads to a black-out period that is inevitable. Based on how close the memory system 100 is to the hard refresh deadline, the impact of the black-out period increases. This is because the tendency to issue REFab commands rather than REFpb commands increases as the hard refresh deadline approaches, and black-outs due to REFab commands have a greater negative impact on performance of the memory system 100. While the inevitable REFab may not be prevented, the impact can be reduced by delaying it using the graded alert levels and their corresponding actions.

The actions taken during the intermediate alert levels, e.g., alert levels 1 and 2 in the example of Table 1, can allow high priority requests (e.g., those that are latency sensitive, timeouts, etc.) to go through while blocking regular memory transactions. Thus, an advantage of this approach is the likelihood of entering higher alert levels, e.g., a critical alert level, decreases. This implies that the chances of a blocking black-out period is reduced as well, which reduces the impact of refresh black-out periods on the system QOS while making sure that the hard refresh deadline is never missed.

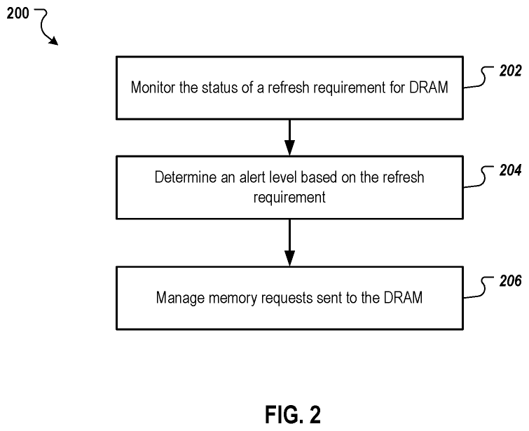

FIG. 2 is a flow diagram of an example process 200 for refreshing DRAM cells. The process 200 can be performed by a memory controller of a DRAM system, e.g., the memory controller 110 of FIG. TA. The DRAM can include DRAM banks arranged in DRAM bank groups that each include one or more DRAM banks. For example, each DRAM bank group can be a bank pair, as described above.

The memory controller monitors the status of a refresh requirement for DRAM (202). The refresh requirement can be a duration of time until a hard refresh deadline will occur absent additional refresh commands being sent to refresh DRAM banks of the DRAM. The hard refresh deadline can be a deadline by which all DRAM banks of the DRAM must be refreshed. As described above, this deadline can change, e.g., be pushed into the future, in response to refresh commands being sent to the DRAM banks.

The memory controller determines an alert level based at least in part on the status of a refresh requirement (204). For example, an alert level manager of the memory controller can determine the alert level based on a current time (tcurrent) and the time at which the hard deadline will occur (tREFmust). In a particular example, the alert level manager can determine the alert level based on the definitions in Table 1 shown above.

The memory controller manages memory requests based on the determined alert level. For example, the memory controller can proactively refresh DRAM banks based on the determined alert level, as described above. In addition, the memory controller can block some types of memory requests based on the determined alert level, as described above. As the alert level increases, the memory controller can proactively refresh additional DRAM banks and/or block additional memory request commands to prevent the occurrence of the hard refresh deadline.

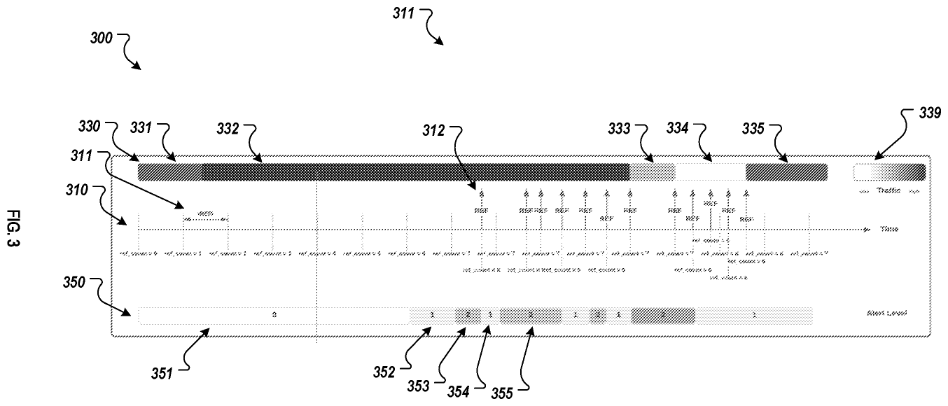

FIG. 3 shows a diagram 300 that includes a timeline 310 of refresh intervals, memory traffic levels, and alert levels. The diagram 300 illustrates the changes in alert levels over time as memory traffic conditions change and REF commands are sent to DRAM. For the purposes of this diagram 300, a REF command represents either a REFab command or a REFpb command to every bank group of the DRAM during a tREFi period.

The diagram 300 includes a traffic level bar 330 that indicates the changing memory traffic levels based on a legend 339 and an alert level bar 350 that indicates the current alert levels as they change over time. The timeline 310 shows the occurrence of refresh intervals (tREFi) 311 over time, the refresh count of a refresh counter, e.g., refresh counter 124 of FIG. 1, and the occurrence of REF commands.

At the beginning of the timeline 310, the refresh count is at zero, the alert level is at zero 351, and the memory traffic is moderate 331. As there are no REF commands sent to the DRAM during the first seven refresh intervals and the memory traffic increases to a higher level 332, the refresh count increments for each refresh interval and the alert level is raised from zero to one 352 and then to two 353 based on the memory system getting closer to a hard refresh deadline that will occur at a refresh count of eight.

In response to the increased alert level, the memory controller can block some memory requests and proactively refresh DRAM banks. For example, after the seventh refresh interval, the memory controller sends a REF command 312 to the DRAM. In response, the refresh counter decrements back to six and the alert level manager reduces the alert level to one 354. At the end of the refresh interval in which the REF command 312 was sent, the refresh counter increments back to seven and the alert level manager raises the alert level back to two 355.

Additional REF commands are sent over time and the refresh counter continues to increment and decrement based on the REF commands and completions of refresh intervals. The alert level manager also continues to update the alert level based on the status of the hard refresh deadline. As the traffic level decreases at 333-335 and the rate of the REF commands increases, the memory controller is able to stay ahead of the hard refresh deadline and the alert level never goes above 2.

Embodiments of the subject matter and the functional operations described in this specification can be implemented in digital electronic circuitry, in tangibly-embodied computer software or firmware, in computer hardware, including the structures disclosed in this specification and their structural equivalents, or in combinations of one or more of them. Embodiments of the subject matter described in this specification can be implemented as one or more computer programs, i.e., one or more modules of computer program instructions encoded on a tangible non transitory program carrier for execution by, or to control the operation of, data processing apparatus. Alternatively or in addition, the program instructions can be encoded on an artificially generated propagated signal, e.g., a machine-generated electrical, optical, or electromagnetic signal, that is generated to encode information for transmission to suitable receiver apparatus for execution by a data processing apparatus. The computer storage medium can be a machine-readable storage device, a machine-readable storage substrate, a random or serial access memory device, or a combination of one or more of them.

The processes and logic flows described in this specification can be performed by one or more programmable computers executing one or more computer programs to perform functions by operating on input data and generating output. The processes and logic flows can also be performed by, and apparatus can also be implemented as, special purpose logic circuitry, e.g., an FPGA (field programmable gate array), an ASIC (application specific integrated circuit), or a GPGPU (General purpose graphics processing unit).

Computers suitable for the execution of a computer program include, by way of example, can be based on general or special purpose microprocessors or both, or any other kind of central processing unit. Generally, a central processing unit will receive instructions and data from a read only memory or a random access memory or both. The essential elements of a computer are a central processing unit for performing or executing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device, e.g., a universal serial bus (USB) flash drive, to name just a few.

Computer readable media suitable for storing computer program instructions and data include all forms of non volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

While this specification contains many specific implementation details, these should not be construed as limitations on the scope of any invention or of what may be claimed, but rather as descriptions of features that may be specific to particular embodiments of particular inventions. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In certain implementations, multitasking and parallel processing may be advantageous.

What is claimed is:

1. A memory system, comprising:
dynamic random-access memory (DRAM) comprising a plurality of DRAM banks arranged in a set of DRAM bank groups each comprising one or more DRAM banks; and
a memory controller for managing the DRAM, the memory controller comprising:
a request scheduler configured to receive memory transactions and send memory request commands to the DRAM banks; and
a refresh scheduler configured to:
monitor a status of a dynamically changing refresh requirement for the DRAM;
determine an alert level for the DRAM based at least in part on a duration of time until a hard refresh deadline; and
manage, based on the determined alert level, the DRAM banks to which refresh commands are sent and the memory transactions for which memory request commands are sent by the request scheduler.

2. The memory system of claim 1, wherein the duration of time until a hard refresh deadline comprises a deadline by which all DRAM banks of the DRAM must be refreshed.

3. The memory system of claim 1, wherein the refresh scheduler is configured to manage the DRAM banks to which refresh commands are sent and the memory transactions for which memory request commands are sent by the request scheduler based further on a priority value for each memory transaction.

4. The memory system of claim 1, wherein the refresh scheduler is configured to manage the DRAM banks to which refresh commands are sent based on a combination of the determined alert level and a status of each DRAM bank.

5. The memory system of claim 4, wherein the status of each DRAM bank comprises an indication of whether the DRAM bank is open or closed.

6. The memory system of claim 4, wherein the refresh scheduler is configured to manage the DRAM banks to which refresh commands are sent based further on a priority value for memory transactions for each DRAM bank.

7. The memory system of claim 1, wherein the refresh scheduler is configured to manage the DRAM banks to which refresh commands are sent by proactively sending precharge commands to DRAM banks based on a combination of the determined alert level and a status of the DRAM banks.

8. The memory system of claim 1, wherein the refresh scheduler is configured to manage the memory transactions for which memory request commands are sent by the request scheduler based on a combination of the determined alert level and a type of memory request command to be sent to each DRAM bank for which a memory transaction has been received.

9. The memory system of claim 8, wherein the refresh scheduler is configured to (i) block activate (ACT) commands for non-priority memory transactions for a first alert level and (ii) block all ACT commands and column read or write (COL) commands for memory transactions for a second alert level that is higher than the first alert level.

10. A method performed by a memory controller configured to manage dynamic random-access memory (DRAM) comprising a plurality of DRAM banks arranged in a set of DRAM bank groups each comprising one or more DRAM banks, the method comprising:
receiving, by a request scheduler of the memory controller, memory transactions for the DRAM;
sending, by the request scheduler, memory request commands to the DRAM banks based on the received memory transactions;
monitoring, by the refresh scheduler, a status of a dynamically changing refresh requirement for the DRAM;
determining, by the refresh scheduler, an alert level for the DRAM based at least in part on a duration of time until a hard refresh deadline; and
managing, by the refresh scheduler and based on the determined alert level, the DRAM banks to which refresh commands are sent and the memory transactions for which memory request commands are sent by the request scheduler.

11. The method of claim 10, wherein the hard refresh deadline comprises a deadline by which all DRAM banks of the DRAM must be refreshed.

12. The method of claim 10, wherein the refresh scheduler manages the DRAM banks to which refresh commands are sent and the memory transactions for which memory request commands are sent by the request scheduler based further on a priority value for each memory transaction.

13. The method of claim 10, wherein the refresh scheduler manages the DRAM banks to which refresh commands are sent based on a combination of the determined alert level and a status of each DRAM bank.

14. The method of claim 13, wherein the status of each DRAM bank comprises an indication of whether the DRAM bank is open or closed.

15. The method of claim 13, wherein the refresh scheduler manages the DRAM banks to which refresh commands are sent based further on a priority value for memory transactions for each DRAM bank.

16. The method of claim 10, wherein the refresh scheduler manages the DRAM banks to which refresh commands are sent by proactively sending precharge commands to DRAM banks based on a combination of the determined alert level and a status of the DRAM banks.

17. The method of claim 10, wherein the refresh scheduler manages the memory transactions for which memory request commands are sent by the request scheduler based on a combination of the determined alert level and a type of memory request command to be sent to each DRAM bank for which a memory transaction has been received.

18. The method of claim 17, wherein the refresh scheduler is configured to (i) block activate (ACT) commands for non-priority memory transactions for a first alert level and (ii) block all ACT commands and column read or write (COL) commands for memory transactions for a second alert level that is higher than the first alert level.

19. A memory controller, comprising:
a request scheduler configured to receive memory transactions and send memory request commands to dynamic random-access memory (DRAM) comprising DRAM banks arranged in a set of DRAM bank groups each comprising one or more DRAM banks; and
a refresh scheduler configured to:
monitor a status of a dynamically changing refresh requirement for the DRAM;
determine an alert level for the DRAM based at least in part on a duration of time until a hard deadline; and
manage, based on the determined alert level, the DRAM banks to which refresh commands are sent and the memory transactions for which memory request commands are sent by the request scheduler.

20. The memory controller of claim 19, wherein the status of the refresh requirement comprises a duration of time until an occurrence of a deadline by which all DRAM banks of the DRAM must be refreshed.
